(19) United States
(12) Patent Application Publication
(10) Pub. No.: US 2006/0214709 A1
(43) Pub. Date: Sep. 28, 2006

(54) Circuit arrangement for generating a synchronization signal

(76) Inventors: Aaron Nygren, Munchen (DE); Patrick Heyne, Munchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/375,569

(22) Filed: Mar. 15, 2006

(30) Foreign Application Priority Data
Mar. 15, 2005 (DE) 10 2005 011 894.1

(51) Int. Cl. H03L 7/06

(52) U.S. Cl. 327/158

(57) ABSTRACT

A circuit arrangement is provided for generating a synchronization signal having signal edge changes whose timings are defined. The arrangement includes a plurality of controllable signal delay arrangements, each including a circuit part with variable signal delay and a circuit part with constant signal delay, where an input signal is supplied to a first controllable signal delay arrangement, a phase detection device including two inputs and one output, and a control circuit that controls the circuit parts with variable signal delay. The input of the control circuit is connected to the output of the phase detection device, and the output of the control circuit is connected to control inputs of the circuit parts with variable signal delay. The input signal is also supplied to the first input of the phase detection device. One output of one of the controllable signal delay arrangements is connected to the second input of the phase detection device. At least one of the controllable signal delay arrangements produces a synchronization signal at the output of the circuit part with variable signal delay.

### CROSS REFERENCE TO RELATED APPLICATIONS

This application claims priority under 35 USC §119 to German Application No. DE 10 2005 011 894.1 filed on Mar. 15, 2005, and titled “Circuit Arrangement for Generating a Synchronization Signal,” the entire contents of which are hereby incorporated by reference.

### FIELD OF THE INVENTION

The present invention relates to a circuit arrangement for generating a synchronization signal.

### BACKGROUND

Complex electrical circuits or parts of them (for example integrated circuits) having a large number of circuit blocks are frequently electrically connected to other complex electrical circuits when used together. In this case, the different complex electrical circuits are often situated on different semiconductor chips or other substrates (for example printed circuit boards). Integrated semiconductor memory circuits in integrated semiconductor memory chips or on appropriate modules may be used as one example of these. On the one hand, these different complex circuits as well as their circuit blocks operate relatively independently of one another, for example, at a different speed (owing to temperature fluctuations and unavoidable tolerance fluctuations in specific electrical parameters during production processes) and asynchronously. On the other hand, the different complex circuits and circuit blocks must communicate electrically with one another, to which the desired (overall) success of an arrangement of such complex circuits and circuit blocks is also geared. This is generally achieved using external clock signals which are supplied to the individual complex circuits and circuit blocks. For example, the task of these external clock signals is to synchronize those electrical signals which are produced in an individual complex circuit (such as a semiconductor circuit) or in an individual circuit block (such as a memory cell array together with read/write amplifiers) with the external clock signal, so that comparable electrical signals from different complex circuits and circuit blocks have a fixed time relationship to one another.

Electrical signals from different complex circuits and circuit blocks are frequently matched to one another, in terms of time, using synchronization signals which are derived from clock signals. In the past, a signal edge change (for example positive=rising edge change of an electrical signal) of the clock signal within a signal period was usually referred to in this case, which edge change then triggers the intended circuit functions when it occurs. In the meantime, however, particularly under the constant pressure to increase the operating speed of electrical circuits, technical progress has advanced to such an extent that the above-described synchronization operations are frequently no longer carried out upon just one of the two edge changes experienced by a synchronization signal within a signal period but rather upon both edge changes, i.e. both on a rising edge of the relevant electrical signal and on a falling edge. Dynamic semiconductor memories (=DRAM) of the DDR type (DDR-DRAM, DDR=Double Data Rate) may be used as one example of this. Both edge changes of the clock signal are used to generate such synchronization signals.

If, then, in the case of synchronization signals, i.e. in the case of signals which are intended to synchronize other electrical signals from a complex circuit or a circuit block with a system clock for a system comprising a plurality of complex circuits or circuit blocks, the rising and falling edges of the two edge changes which occur within a signal period are relatively close to one another (i.e. the so-called duty ratio differs considerably from 50%, with the duty ratio specifying the [for example percentage] proportion of time taken up by one of the two signal levels of the [digital] signal within the signal period) within a signal period (for example on account of changes which the signal has made on its way through a complex circuit), it is difficult to carry out the abovementioned synchronization operation; and it is all the more difficult, the shorter the signal period. The reason for this difficulty is that the interval of time between the two edge changes (which rapidly follow one another) in a signal period is so short that it is scarcely possible to carry out synchronization anymore.

Furthermore, it has also proved to be disadvantageous to use both edge changes of the clock signal to generate a synchronization signal. This is because, if the two edge changes of the clock signal have interference, for example jitter or superimposed interference signal spikes, the interference of both edge changes has an effect on the synchronization signal.

### SUMMARY OF THE INVENTION

The present invention provides a circuit arrangement which converts a given signal to a synchronization signal having a phase shift that is as exact as possible with respect to the given signal.

In accordance with the present invention, a circuit arrangement is provided for generating at least one synchronization signal having defined signal edge changes. The circuit arrangement comprises a plurality of at least two controllable signal delay arrangements, with each controllable signal delay arrangement including a circuit part with variable signal delay and a circuit part with constant signal delay, and with an input signal being supplied to the first controllable signal delay arrangement. The circuit arrangement further comprises a phase detection device including two inputs and one output, a control circuit to control the circuit parts with variable signal delay, with the input of the control circuit being connected to the output of the phase detection device and the output of the control circuit being connected to control inputs of the circuit parts with variable signal delay. The input signal is also supplied to the first input of the phase detection device, one output of one of the controllable signal delay arrangements is connected to the second input of the phase detection device, and the output signal from one of the circuit parts with variable signal delay is used as a first synchronization signal.

The above and still further features and advantages of the present invention will become apparent upon consideration of the following detailed description of specific embodiments thereof, particularly when taken in conjunction with the accompanying drawings wherein like reference designations in the various figures are utilized to designate like components.

### BRIEF DESCRIPTION OF THE DRAWINGS

FIG. 1 depicts a circuit arrangement including a chain of controllable signal delay arrangements arranged in series in accordance with the present invention.

FIG. 2 depicts a circuit arrangement including a chain of controllable signal delay arrangements arranged in series in accordance with another embodiment of the present invention.

FIG. 3 depicts a circuit arrangement including a chain of controllable signal delay arrangements in accordance with a further embodiment of the present invention.

FIG. 4 depicts a circuit arrangement including a chain of controllable signal delay arrangements in accordance with still another embodiment of the present invention.

FIG. 5 depicts a circuit arrangement including a chain of controllable signal delay arrangements in accordance with yet another embodiment of the present invention.

FIG. 6 depicts a circuit arrangement including a chain of controllable signal delay arrangements in accordance with another embodiment of the present invention.

### DETAILED DESCRIPTION

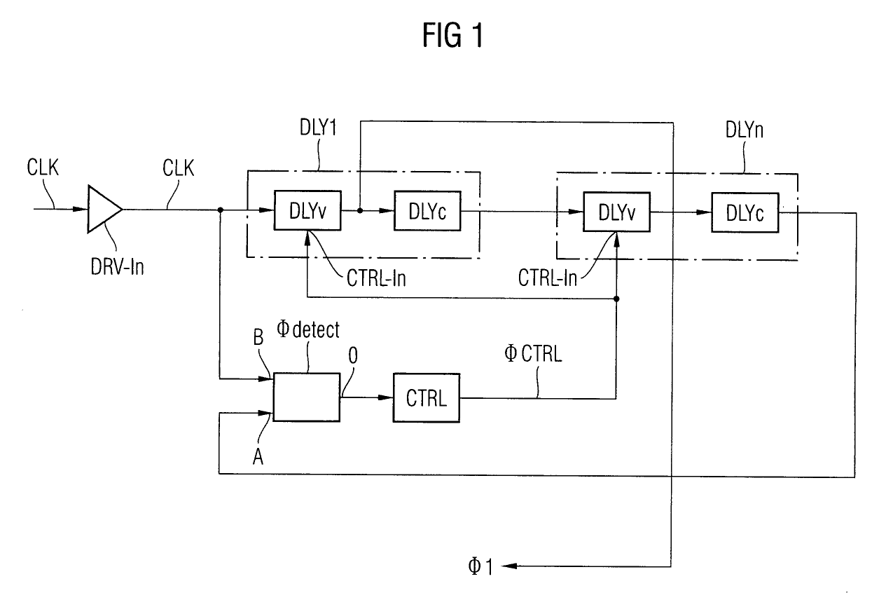

FIG. 1 depicts a first embodiment of the present invention. In this case, a chain of (in the present exemplary embodiment: two) controllable signal delay arrangements DLY1, DLYn are arranged in series. An input signal CLK is supplied to the first controllable signal delay arrangement DLY1. FIG. 1 also shows a first advantageous development of the inventive circuit arrangement, namely an input driver circuit DRV-In which is first of all supplied with the input signal CLK and from which, following amplification and, if necessary, reshaping and/or inversion by the input driver circuit DRV-In, the input signal CLK is supplied to the first controllable signal delay arrangement DLY1. Each of the controllable signal delay arrangements DLY1, DLYn comprises a circuit part DLYv with variable signal delay and a circuit part DLYc with constant signal delay. The input signal CLK is also supplied to a first input B of the phase detection device Φdetect whose operation will be explained in more detail below. The output O of the phase detection device Φdetect is connected to the control circuit CTRL, whose output signal, as the control signal ΦCTRL, is connected to control inputs CTRL-In of the circuit parts DLYv with variable signal delay in the controllable signal delay arrangements DLY1, DLYn. In the case of each circuit part DLYv with variable signal delay, said control signal is used to control the delay duration of the signal that is supplied to the signal input of said circuit part (in the case of the circuit part DLYv with variable signal delay in the first signal delay arrangement DLY1, this signal that is supplied to its signal input is the input signal CLK). The output of the circuit part DLYc with constant signal delay in the last signal delay arrangement DLYn is supplied to the second input A of the phase detection device Φdetect.

The variable signal delay in the circuit parts DLYv with variable signal delay is controlled by the phase detection device Φdetect and the control circuit CTRL as follows: When the input signal CLK is applied to the entire circuit arrangement, this input signal CLK is applied to the first input B of the phase detection device Φdetect and to the input of the first controllable signal delay arrangement DLY1. If the input signal CLK then undergoes an edge change of a predetermined type as it progresses further (it is assumed, for the explanation below, that this edge change is a positive edge change), the occurrence of this edge change is also supplied, in the form of a signal, to the first input B of the phase detection device Φdetect and is applied to the latter. Irrespective of this, the input signal CLK is simultaneously delayed using the chain of controllable signal delay arrangements DLY1, DLYn and is then supplied, in a manner such that it is delayed relative to the input signal CLK, to the second input A of the phase detection device Φdetect.

This delay gives rise to a phase shift between the signals which are supplied to the two inputs A and B of the phase detection device Φdetect (for example a phase shift between the rising edges of these two signals; the same respectively applies, by analogy, to falling edges in this case and in the text below, with, however, those skilled in the art having to decide, when designing the respective circuit, between those circuits which are designed to evaluate rising edges and those circuits which are designed to evaluate falling edges). This phase shift results from a comparison of the signal which has been delayed and is applied to the second input A with the next edge change of the same type (in this case: a rising edge change) that occurs in the input signal CLK at the first input B of the phase detection device Φdetect. The phase detection device Φdetect detects this phase shift and signals the detection result to the control circuit CTRL which uses the latter to generate the control signal ΦCTRL. The control signal ΦCTRL is supplied, via the output of the control circuit CTRL, to the control inputs CTRL-In of the circuit parts DLYv with variable signal delay in the controllable signal delay arrangements DLY1, DLYn.

The value of the control signal ΦCTRL determines the value of the signal delay times used in the circuit parts DLYv with variable signal delay in the controllable signal delay arrangements DLY1, DLYn. In this case, the signal delay times used in the circuit parts DLYv with variable signal delay in the controllable signal delay arrangements DLY1, DLYn are changed using the control signal ΦCTRL until the abovementioned phase shift is equal to zero.

As long as the phase shift between the two signals which are applied to the inputs A and B of the phase detection device Φdetect is such that a (an assumedly) rising edge of the signal that is applied to the second input A occurs at a time after the rising edge of the signal that is applied to the first input B, the value of the control signal ΦCTRL is changed in such a manner that the delay times which occur in the circuit parts DLYv with variable signal delay in the controllable signal delay arrangements DLY1, DLYn are reduced. If, however, the rising edge of the signal that is applied to the second input A occurs once again at a time before the rising edge of the signal that is applied to the first input B, the delay times which occur in the circuit parts DLYv with variable signal delay in the controllable signal delay arrangements DLY1, DLYn are increased.

And when (at some time) the phase shift between the signals which are applied to the two inputs A and B is equal to zero, the control signal ΦCTRL has a value that causes the effective signal delay times (which have been set up to that point) of the circuit parts DLYv with variable signal delay in the controllable signal delay arrangements DLY1, DLYn to remain constant.

The entire arrangement is thus stabilized like a DLL circuit (DLL=Delay Lock Loop) in such a manner that the chain of controllable signal delay arrangements DLY1, DLYn is used to delay the input signal CLK until there is no longer any phase shift between the signals which are applied to the inputs A and B of the phase detection device Φdetect. As soon as this situation has occurred, the control circuit is stable; the desired stable delay relationships and thus also the phase relationships for the input signal CLK are present.

In this case, the (assumedly rising) signal edge of the synchronization signal Φ1 which is applied to, and can be tapped off from, the connecting line between the circuit part DLYv with variable signal delay and the circuit part DLYc with constant signal delay in the first controllable signal delay arrangement DLY1 is delayed, with respect to the input signal CLK, by a period of time that is determined by the control signal ΦCTRL.

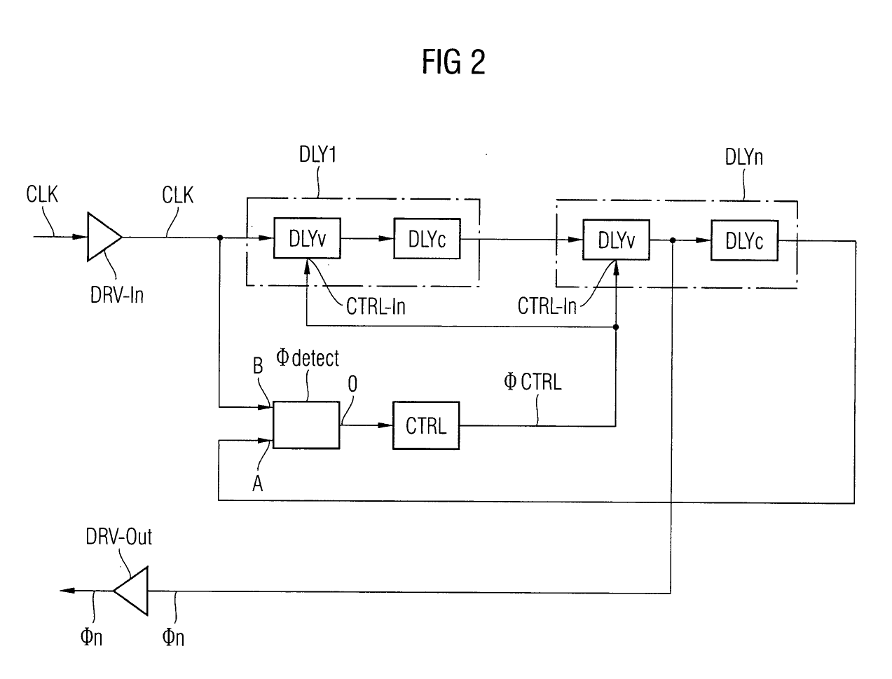

FIG. 2 shows a variant of the inventive circuit shown in FIG. 1. Said variant differs from the latter only in two respects:

On the one hand, the synchronization signal is not tapped off, as the synchronization signal Φ1, from the connecting line between the circuit part DLYv with variable signal delay and the circuit part DLYc with constant signal delay in the first controllable signal delay arrangement DLY1 but rather is tapped off, as the synchronization signal Φn, from the connecting line between the circuit part DLYv with variable signal delay and the circuit part DLYc with constant signal delay in the last (in this case synonymous with: the second) controllable signal delay arrangement DLYn. Compared to the synchronization signal Φ1, this results in the signal edge (which is likewise assumed to be rising again) of the synchronization signal Φn being additionally offset, in time, by half the amount of time by which the signal that is applied to the second input A of the phase detection device Φdetect has been delayed with respect to the input signal CLK.

On the other hand, the inventive circuit arrangement shown in FIG. 2 also has a special development at its circuit output: the synchronization signal Φn is first of all supplied to an output driver circuit DRV-Out, is amplified and, if necessary, reshaped and/or inverted by the latter, and is only then made available to further circuits, circuit blocks etc. for further use.

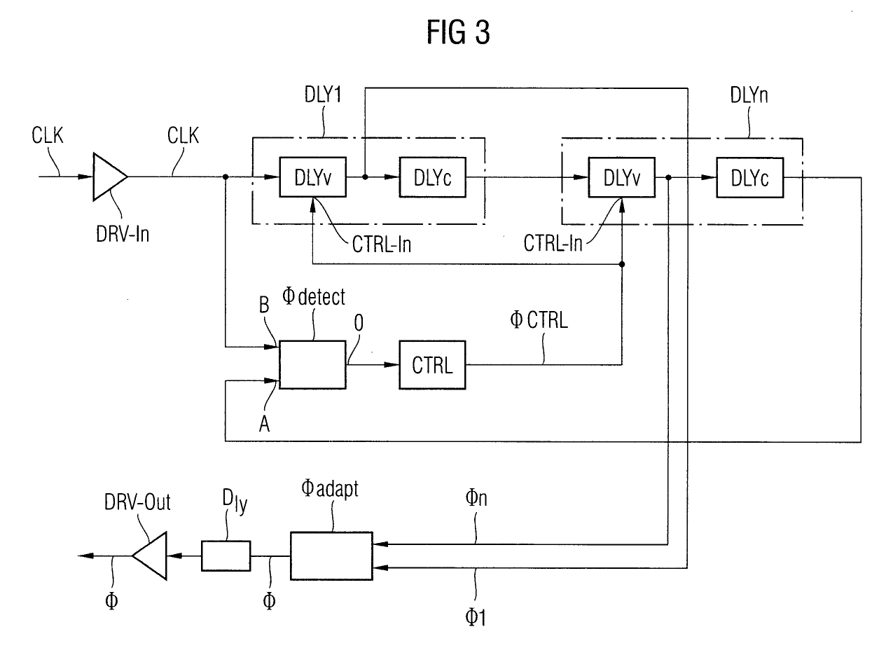

FIG. 3 shows one advantageous development of the present invention. In this case, the inventive circuit arrangement has two synchronization signals Φ1, Φn which, as a combination, as it were, of the teaching from the first two exemplary embodiments shown in FIGS. 1 and 2, are tapped off, on the one hand, from the connecting line between the circuit part DLYv with variable signal delay and the circuit part DLYc with constant signal delay in the first controllable signal delay arrangement DLY1 and are tapped off, on the other hand, between the circuit part DLYv with variable signal delay and the circuit part DLYc with constant signal delay in the last (DLYn) of the controllable signal delay arrangements DLY1, DLYn. Both synchronization signals Φ1, Φn are synchronized with the input signal CLK. They therefore have the same time profiles as the synchronization signals Φ1, Φn shown in FIGS. 1 and 2.

In the present embodiment according to FIG. 3, both synchronization signals Φ1, Φn are supplied to a respective input of a phase matching device Φadapt. The phase matching device Φadapt is preferably formed by an RS flipflop. This phase matching device Φadapt uses the two synchronization signals Φ1, Φn to generate a common synchronization signal Φ having a duty ratio which is, as accurately as possible, 50%, in particular a common synchronization signal Φ having edge changes which are as equidistant as possible. In the case of this common synchronization signal Φ, the two edge changes (i.e. the rising edge change and the falling edge change) are synchronized to one given edge change of the input signal CLK. This has the advantage that external circuits can be synchronized very accurately since the common synchronization signal Φ is free from disturbing influences with which the other edge of the input signal CLK may be encumbered. The common synchronization signal Φ is formed according to the following scheme:

On account of the chain (which operates as a DLL circuit) of two controllable signal delay arrangements DLY1, DLYn together with the associated phase detection device Φdetect and control circuit CTRL, the two synchronization signals Φ1, Φn which are supplied to the phase matching device Φadapt have different time offsets from one another with respect to the original input signal CLK. Every time one of the two supplied synchronization signals Φ1, Φn has one of the assumedly positive (the negative edge changes could also be used, as noted above) edge changes, which corresponds to the (assumedly) positive edge change of the input signal CLK, the output signal (which is the common synchronization signal Φ) from the phase matching device Φadapt has a positive or negative edge change. Each of these positive and negative edge changes is synchronized with the original input signal CLK and has a resultant constant phase shift with respect to these edge changes. Furthermore, in this embodiment, the interval between two successive edge changes of the common synchronization signal Φ is equal to half the period duration of the common synchronization signal Φ. The common synchronization signal Φ thus has edge changes (at equal time intervals) with a duty ratio of 50% in this exemplary embodiment. This common synchronization signal Φ makes it possible to synchronize other circuits, which need to be synchronized with the common synchronization signal Φ, at a time interval of half the period duration of the input signal CLK despite evaluating only one of the two edge changes of the input signal CLK (for example the rising edge), which is advantageous, in particular, when the inventive circuit arrangement is intended to interact with complex electrical circuits, or parts of the latter, which operate at very high speed.

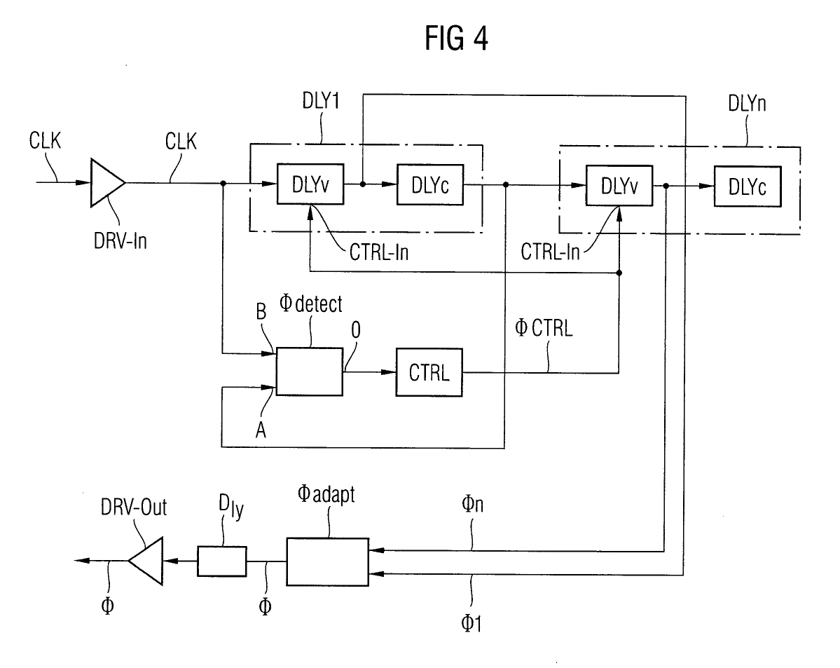

The embodiment shown in FIG. 4 differs from that shown in FIG. 3 only insofar as the signal which is applied to the second input A of the phase detection device Φdetect is not tapped off from the output of the last of the controllable signal delay arrangements DLY1, DLYn, but rather from the output of one of the controllable signal delay arrangements which are arranged upstream of the last of the controllable signal delay arrangements DLY1, DLYn, that is to say, in the present case of two controllable signal delay arrangements DLY1, DLYn, from the output of the first controllable signal delay arrangement DLY1. In this embodiment, the control resolution of the control signal ΦCTRL is improved on the embodiment shown in FIG. 3 since changes in the control signal ΦCTRL have a more rapid effect on the circuit parts DLYv with variable signal delay (control loop which is short in terms of time).

The inventive circuit arrangements shown in FIGS. 3 and 4 have a special development at their respective circuit output: the common synchronization signal Φ which is generated by the phase matching device Φadapt is first of all supplied to an output driver circuit DRV-Out, is amplified and, if necessary, reshaped and/or inverted by the latter, and is only then made available to further circuits, circuit blocks etc. for further use. In this case, yet another intrinsic signal delay generally occurs between the phase matching device Φadapt and the output driver circuit DRV-Out, said signal delay causing the signal which leaves the output driver circuit DRV-Out to have the same phase angle as the input signal CLK when the signals which are applied to the inputs A, B of the phase detection device Φdetect have the same phase angle relative to one another. This is schematically shown in FIGS. 3 and 4 by the delay block D_{ly}.

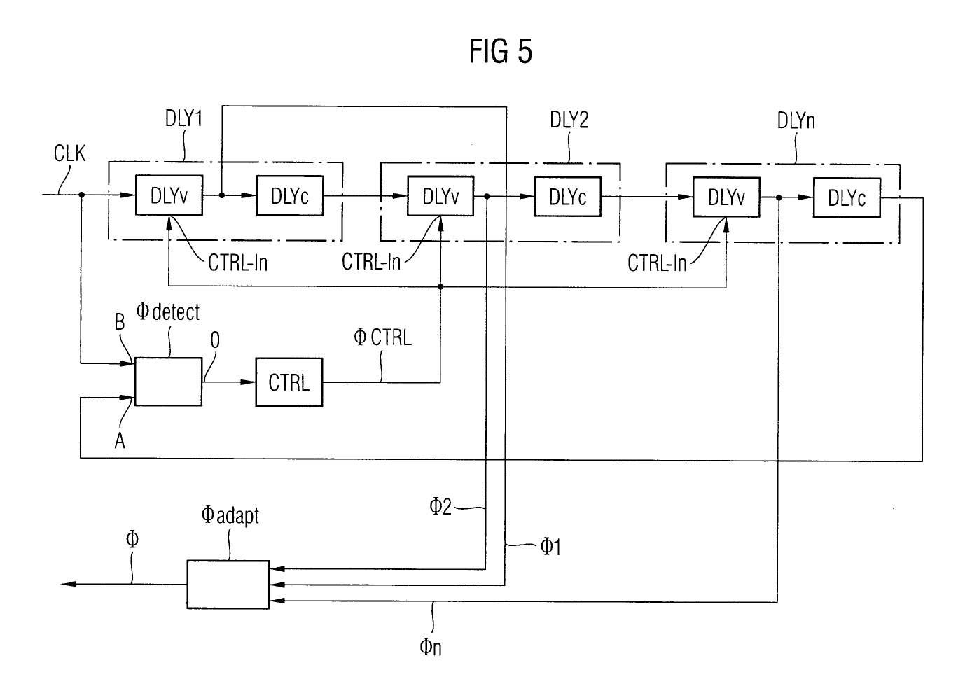

FIG. 5 shows another advantageous embodiment of the present invention. Its basic design is similar to the embodiment already presented in FIG. 3. However, it has three controllable signal delay arrangements DLY1, DLY2 and DLYn each having a circuit part DLYv with variable signal delay and a circuit part DLYc with constant signal delay. Each circuit part DLYv has a control input CTRL-In which is used to supply the control signal ΦCTRL from the control circuit CTRL to the circuit parts DLYv with variable signal delay. A tap, from which the input signal CLK which has been delayed up to the respective tap is tapped off and is supplied, as a respective synchronization signal Φ1 or Φ2 or Φn, to a respective input of the phase matching device Φadapt, is provided, in each of the controllable signal delay arrangements DLY1, DLY2 and DLYn, between their circuit part DLYv with variable signal delay and their circuit part DLYc with constant signal delay. Each time a positive edge change, for example, arrives at one of these inputs, the phase matching device Φadapt generates an edge change of its output signal (=common synchronization signal Φ), so that this common synchronization signal Φ has three edge changes which occur at equal time intervals and are synchronized with the edge change of the prescribed type of the input signal CLK during a period duration of the input signal CLK. In this case, the edge changes of the common synchronization signal Φ are alternately positive and negative.

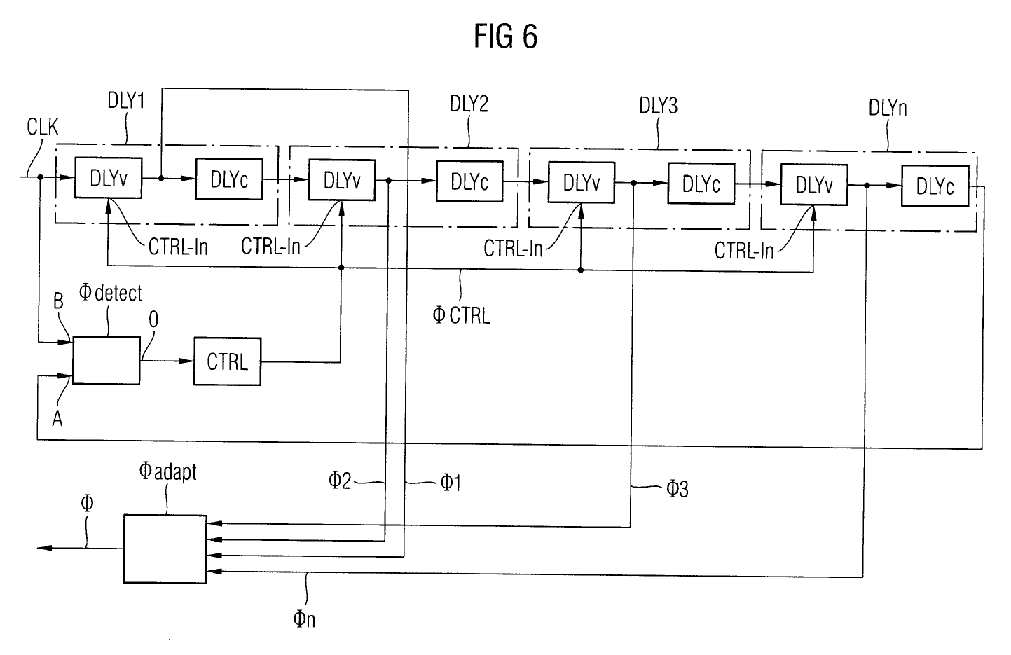

A similar situation applies to the advantageous embodiment shown in FIG. 6: in this case, four controllable signal delay arrangements DLY1, DLY2, DLY3 and DLYn are arranged in series. Analogously to the embodiments shown in FIGS. 3 and 4, said signal delay arrangements are connected to the control circuit CTRL and to the phase matching device Φadapt. In this case, the resultant common synchronization signal Φ has four edge changes which are at equal time intervals, are synchronized with the input signal CLK and are alternately positive and negative within the period duration of the input signal CLK. This common synchronization signal Φ makes it possible to synchronize signals from other circuits, circuit blocks etc. in an even more accurate manner than with the individually supplied synchronization signals Φ1, Φn according to the above-described embodiments.

The embodiments shown in FIGS. 5 and 6 can also be configured without the phase matching device Φadapt, so that three Φ1, Φ2 and Φn) or four synchronization signals Φ1 to Φn with different time offsets are available for further use. This has the advantage that synchronization signals having different phase shifts with respect to the input signal CLK are available for synchronizing external circuit parts, thus greatly simplifying, under certain circumstances, the development of such external circuit parts which need to be synchronized.

It has been assumed, in each of the above-described embodiments, that the individual circuit parts DLYv with variable signal delay each have the same delay response as one another and that the individual circuit parts DLYc with constant signal delay likewise each have the same delay response as one another. When generating a plurality of synchronization signals Φ1, Φ2, . . . , Φn, this results in the various controllable signal delay arrangements DLY1, DLY2, . . . , DLYn respectively reacting in the same manner in terms of time and in the synchronization signals Φ1, Φ2, . . . , Φn having equidistant edge changes. However, it is also conceivable for individual circuit parts DLYv with variable signal delay (and/or individual circuit parts DLYc with constant signal delay) to have delay responses which are at least partially different from one another. The different controllable signal delay arrangements DLY1, DLY2, . . . , DLYn and, consequently, the plurality of generated synchronization signals Φ1, Φ2, . . . , Φn then no longer have equal time intervals between their edge changes but rather those which result from the differences in the delay responses of the individual circuit parts DLYv with variable signal delay (and/or the individual circuit parts DLYc with constant signal delay).

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

List of Reference Symbols

Φ1, . . . , Φn Synchronization signals

Φ Common synchronization signal

CLK Input signal

DLY1, . . . , DLYn Signal delay arrangements

DLYv, DLYc Circuit part with variable time delay and circuit part with constant time delay

B, A Inputs

O Output

Φdetect Phase detection device

Φadapt Phase matching device

CTRL Control circuit

CTRL-In Control input

DRV-In, DRV-Out Input driver circuit, output driver circuit

D_{ly} Delay block

What is claimed:

1. A circuit arrangement for generating at least one synchronization signal having defined signal edge changes, the circuit arrangement comprising:
a plurality of at least two controllable signal delay arrangements, each controllable signal delay arrangement including a circuit part with variable signal delay and a circuit part with constant signal delay, wherein an input signal is supplied to a first controllable signal delay arrangement;
a phase detection device including two inputs and one output; and
a control circuit to control the circuit parts with variable signal delay, wherein an input of the control circuit is connected to the output of the phase detection device and an output of the control circuit is connected to control inputs of the circuit parts with variable signal delay;
wherein the input signal is also supplied to the first input of the phase detection device, one output of one of the controllable signal delay arrangements is connected to the second input of the phase detection device, and the output signal from one of the circuit parts with variable signal delay is used as a first synchronization signal.

2. The circuit arrangement of claim 1, wherein the number of controllable signal delay arrangements from two to four.

3. The circuit arrangement of claim 1, wherein the circuit arrangement is designed such that an output signal from another of the circuit parts with variable signal delay is used as a second synchronization signal.

4. The circuit arrangement of claim 1, further comprising an input driver circuit that is supplied with the input signal and is arranged upstream from the first controllable signal delay arrangement.

5. The circuit arrangement of claim 1, wherein the first synchronization signal is supplied to an output driver circuit.

6. The circuit arrangement of claim 1, further comprising a phase matching device to receive a plurality of synchronization signals so as to generate a common synchronization signal.

7. The circuit arrangement of claim 6, wherein the phase matching device is designed such that the common synchronization signal has edge changes that are equidistant and have been delayed in time with respect to the input signal.

8. The circuit arrangement of claim 6, wherein the phase matching device comprises an RS flipflop circuit.

9. The circuit arrangement of claim 6, wherein the common synchronization signal is supplied to an output driver circuit.

10. A method for generating at least one synchronization signal having defined signal edge changes, the method comprising:
providing a circuit arrangement including a plurality of at least two controllable signal delay arrangements, each controllable signal delay arrangement including a circuit part with variable signal delay and a circuit part with constant signal delay, a phase detection device including two inputs and one output, and a control circuit to control the circuit parts with variable signal delay, wherein an input of the control circuit is connected to the output of the phase detection device, an output of the control circuit is connected to control inputs of the circuit parts with variable signal delay, and one output of one of the controllable signal delay arrangements is connected to the second input of the phase detection device;
supplying an input signal to a first controllable signal delay arrangement and to the first input of the phase detection device; and
using the output signal from one of the circuit parts with variable signal delay as a first synchronization signal.

11. The method of claim 10, wherein the number of controllable signal delay arrangements from two to four.

12. The method of claim 10, further comprising:
using an output signal from another of the circuit parts with variable signal delay as a second synchronization signal.

13. The method of claim 10, further comprising:
supplying an input driver circuit that is arranged upstream from the first controllable signal delay arrangement with the input signal.

14. The method of claim 10, further comprising:
supplying the first synchronization signal to an output driver circuit.

15. The method of claim 10, further comprising:
supplying the first synchronization signal to an output driver circuit.

16. The method of claim 10, wherein the output signals from each of the circuit parts with variable signal delay are used as a plurality of synchronization signals, and the method further comprises:
providing the plurality of synchronization signals to a phase matching device so as to generate a common synchronization signal.

17. The method of claim 16, wherein the common synchronization signal that is generated has edge changes that are equidistant and have been delayed in time with respect to the input signal.

18. The method of claim 16, wherein the phase matching device comprises an RS flipflop circuit.

19. The method of claim 16, further comprising:
supplying the common synchronization signal to an output driver circuit.
